(19) United States
(12) Patent Application Publication
(10) Pub. No.: US 2017/0206172 A1
(43) Pub. Date: Jul. 20, 2017

(54) TEHCNIQUES WITH OS- AND APPLICATION- TRANSPARENT MEMORY COMPRESSION

(71) Applicant: SK hynix Inc., Gyeonggi-do (KR)

(72) Inventors: Kenneth C. MA, Cupertino, CA (US); Dongwook SUH, Saratoga, CA (US)

(21) Appl. No.: 15/370,890

(22) Filed: Dec. 6, 2016

Related U.S. Application Data
(60) Provisional application No. 62/311,282, filed on Mar. 21, 2016.
(60) Provisional application No. 62/280,430, filed on Jan. 19, 2016.

(51) Int. Cl. G06F 12/12; G11C 16/26; G06F 3/06; G11C 16/08; G06F 12/0891; G06F 12/0815; G11C 16/10; G11C 16/16

(52) U.S. Cl. CPC G06F 12/12; G11C 16/10; G11C 16/26; G11C 16/16; G11C 16/08; G06F 12/0891; G06F 12/0815; G06F 3/0608; G06F 3/0659; G06F 3/0661; G06F 3/0685; G06F 2212/1044; G06F 2212/401; G06F 2212/60; G06F 2212/621; G06F 2212/69

(57) ABSTRACT

Memory systems may include a memory storage including a fast memory portion and a slow memory portion, a software page remapping kernel driver (SPRKD) suitable for intercepting a memory management command generated by an operating system, at least one of compressing data to be written from the fast memory portion to the slow memory portion prior to execution of the operating system memory management command, and decompressing data to be written from the slow memory portion to the fast memory portion prior to execution of the operating system memory management command, and transferring either the compressed data to be written to the slow memory portion or the decompressed data to be written to the fast memory portion, and a controller suitable for executing the memory management command after the transferring by the SPRKD such that the compressing or decompressing of data is performed transparent to the operating system.

### CROSS-REFERENCE TO RELATED APPLICATIONS

This application claims the benefit of U.S. Provisional Application No. 62/311,282 filed Mar. 21, 2016 and U.S. Provisional Application No. 62/280,430 filed Jan. 19, 2016, the entire contents of which are incorporated herein by reference.

### BACKGROUND

1. Field

Exemplary embodiments of the present disclosure relate to a memory system and an operating method thereof.

2. Description of the Related Art

The computer environment paradigm has shifted to ubiquitous computing systems that can be used anytime and anywhere. Due to this fact, the use of portable electronic devices such as mobile phones, digital cameras, and notebook computers has rapidly increased. These portable electronic devices generally use a memory system having memory devices, that is, a data storage device. The data storage device is used as a main memory device or an auxiliary memory device of the portable electronic devices.

Data storage devices using memory devices provide excellent stability, durability, high information access speed, and low power consumption, since they have no moving parts. Examples of data storage devices having such advantages include universal serial bus (USB) memory devices, memory cards having various interfaces, and solid state drives (SSD).

Fast memory is a critical resource in computing systems and increased memory capacity is in high demand. Memory compression is utilized to increase memory capacity, and there exists a need for improved memory compression in memory systems, methods, devices, and processes.

### SUMMARY

Aspects of the invention include memory systems. The memory systems may include a memory storage including a fast memory portion and a slow memory portion, a software page remapping kernel driver (SPRKD) suitable for intercepting a memory management command generated by an operating system, at least one of compressing data to be written from the fast memory portion to the slow memory portion prior to execution of the operating system memory management command, and decompressing data to be written from the slow memory portion to the fast memory portion prior to execution of the operating system memory management command, and transferring either the compressed data to be written to the slow memory portion or the decompressed data to be written to the fast memory portion, and a controller suitable for executing the memory management command after the transferring by the SPRKD such that the compressing or decompressing of data is performed transparent to the operating system.

Further aspects of the invention include methods. The methods may include intercepting, with a software page remapping kernel driver (SPRKD), a memory management command generated by an operating system, at least one of, compressing, with the SPRKD, data to be written from a fast memory portion of a memory storage to a slow memory portion of the memory storage prior to execution of the operating system memory management command, and decompressing, with the SPRKD, data to be written from the slow memory portion to the fast memory portion prior to execution of the operating system memory management command, and transferring, with the SPRKD, either the compressed data to be written to the slow memory portion or the decompressed data to be written to the fast memory portion, and executing, with a controller, the memory management command after the transferring by the SPRKD such that the compressing or decompressing of data is performed transparent to the operating system.

Additional aspects of the invention include memory devices. The memory devices may include a memory storage including a fast memory portion and a slow memory portion, a software page remapping kernel driver (SPRKD) configured to intercept a memory management command generated by an operating system, at least one of, compress data to be written from the fast memory portion to the slow memory portion prior to execution of the operating system memory management command, and decompress data to be written from the slow memory portion to the fast memory portion prior to execution of the operating system memory management command, and transfer either the compressed data to be written to the slow memory portion or the decompressed data to be written to the fast memory portion, and a controller configured to execute the memory management command after the transferring by the SPRKD such that the compressing or decompressing of data is performed transparent to the operating system.

### BRIEF DESCRIPTION OF THE DRAWINGS

FIG. 1 is a block diagram schematically illustrating a memory system in accordance with an embodiment of the present invention.

FIG. 2 is a block diagram illustrating a memory system in accordance with an embodiment of the present invention.

FIG. 3 is a circuit diagram illustrating a memory block of a memory device in accordance with an embodiment of the present invention.

FIG. 4 is a diagram of an example system with a hybrid memory for compression and decompression in accordance with aspects of the invention.

FIG. 5 is a diagram of an example system with a hybrid memory for compression and decompression according to aspects of the invention.

FIG. 6 is a diagram of an example system with a hybrid memory for compression and decompression according to aspects of the invention.

FIG. 7 is a diagram of an example system for page remapping in accordance with aspects of the invention.

FIG. 8 is a diagram of a CPU system/process for page remapping and compression/decompression according to aspects of the invention.

FIG. 9 is a flowchart of steps in a method for page remapping and compression/decompression in accordance with aspects of the invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The invention can be implemented in numerous ways, including as a process; an apparatus; a system; a composition of matter; a computer program product embodied on a computer readable storage medium; and/or a processor, such as a processor suitable for executing instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being suitable for performing a task may be implemented as a general component that is temporarily suitable for performing the task at a given time or a specific component that is manufactured to perform the task. As used herein, the term ‘processor’ refers to one or more devices, circuits, and/or processing cores suitable for processing data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

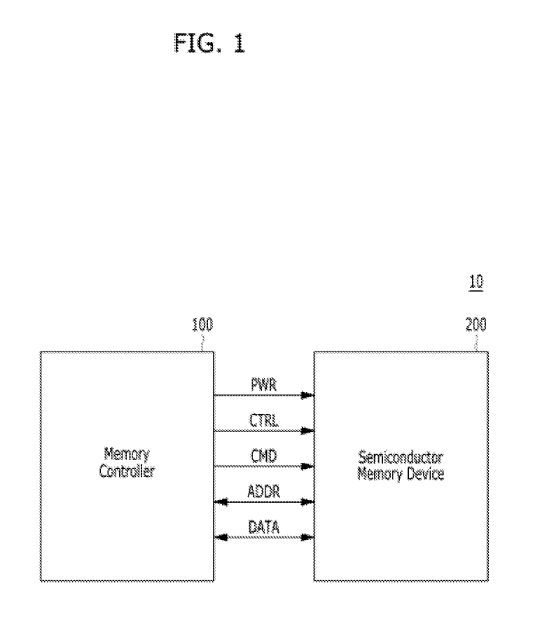

FIG. 1 is a block diagram schematically illustrating a memory system 10 in accordance with an embodiment of the present invention.

Referring FIG. 1, the memory system 10 may include a memory controller 100 and a semiconductor memory device 200.

The memory controller 100 may control overall operations of the semiconductor memory device 200.

The semiconductor memory device 200 may perform one or more erase, program, and read operations under the control of the memory controller 100. The semiconductor memory device 200 may receive a command CMD, an address ADDR and data DATA through input/output lines. The semiconductor memory device 200 may receive power PWR through a power line and a control signal CTRL through a control line. The control signal may include a command latch enable (CLE) signal, an address latch enable (ALE) signal, a chip enable (CE) signal, a write enable (WE) signal, a read enable (RE) signal, and so on.

The memory controller 100 and the semiconductor memory device 200 may be integrated in a single semiconductor device. For example, the memory controller 100 and the semiconductor memory device 200 may be integrated in a single semiconductor device such as a solid state drive (SSD). The solid state drive may include a storage device for storing data therein. When the semiconductor memory system 10 is used in an SSD, operation speed of a host (not shown) coupled to the memory system 10 may remarkably improve.

The memory controller 100 and the semiconductor memory device 200 may be integrated in a single semiconductor device such as a memory card. For example, the memory controller 100 and the semiconductor memory device 200 may be integrated in a single semiconductor device to configure a memory card such as a PC card of personal computer memory card international association (PCMCIA), a compact flash (CF) card, a smart media (SM) card, a memory stick, a multimedia card (MMC), a reduced-size multimedia card (RS-MMC), a micro-size version of MMC (MMCmicro), a secure digital (SD) card, a mini secure digital (miniSD) card, a micro secure digital (microSD) card, a secure digital high capacity (SDHC), and a universal flash storage (UFS).

For another example, the memory system 10 may be provided as one of various elements including an electronic device such as a computer, an ultra-mobile PC (UMPC), a workstation, a net-book computer, a personal digital assistant (PDA), a portable computer, a web tablet PC, a wireless phone, a mobile phone, a smart phone, an e-book reader, a portable multimedia player (PMP), a portable game device, a navigation device, a black box, a digital camera, a digital multimedia broadcasting (DMB) player, a 3-dimensional television, a smart television, a digital audio recorder, a digital audio player, a digital picture recorder, a digital picture player, a digital video recorder, a digital video player, a storage device of a data center, a device capable of receiving and transmitting information in a wireless environment, one of electronic devices of a home network, one of electronic devices of a computer network, one of electronic devices of a telematics network, a radio-frequency identification (RFID) device, or elements devices of a computing system.

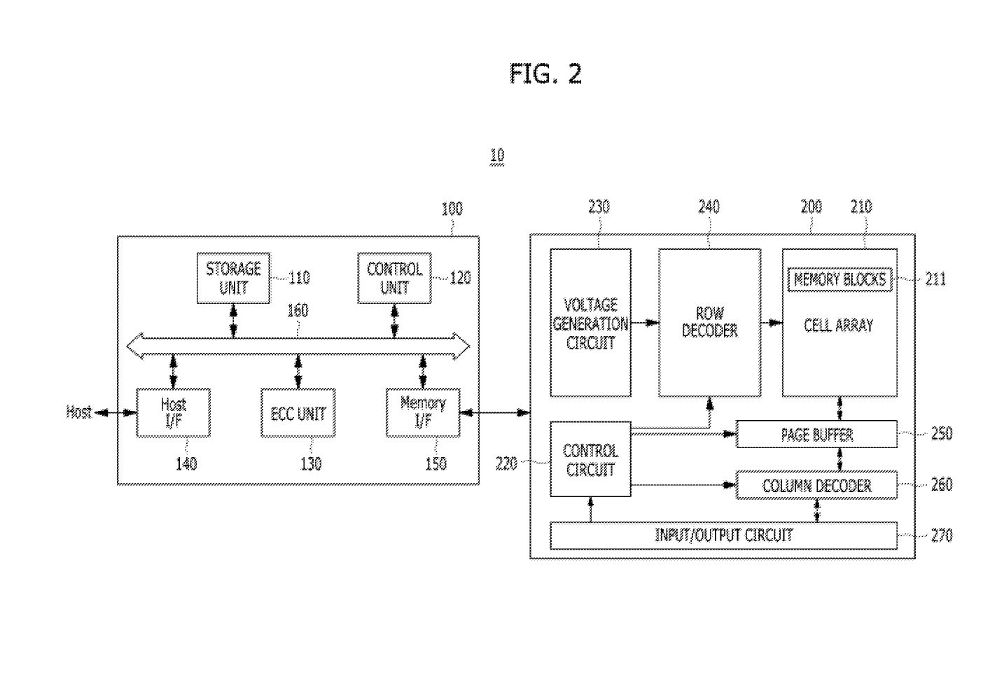

FIG. 2 is a detailed block diagram illustrating a memory system in accordance with an embodiment of the present invention. For example, the memory system of FIG. 2 may depict the memory system 10 shown in FIG. 1.

Referring to FIG. 2, the memory system 10 may include a memory controller 100 and a semiconductor memory device 200. The memory system 10 may operate in response to a request from a host device, and in particular, store data to be accessed by the host device.

The host device may be implemented with any one of various kinds of electronic devices. In some embodiments, the host device may include an electronic device such as a desktop computer, a workstation, a three-dimensional (3D) television, a smart television, a digital audio recorder, a digital audio player, a digital picture recorder, a digital picture player, a digital video recorder and a digital video player. In some embodiments, the host device may include a portable electronic device such as a mobile phone, a smart phone, an e-book, an MP3 player, a portable multimedia player (PMP), and a portable game player.

The memory device 200 may store data to be accessed by the host device.

The memory device 200 may be implemented with a volatile memory device such as a dynamic random access memory (DRAM) and a static random access memory (SRAM) or a non-volatile memory device such as a read only memory (ROM), a mask ROM (MROM), a programmable ROM (PROM), an erasable programmable ROM (EPROM), an electrically erasable programmable ROM (EEPROM), a ferroelectric random access memory (FRAM), a phase change RAM (PRAM), a magnetoresistive RAM (MRAM) and a resistive RAM (RRAM).

The controller 100 may control storage of data in the memory device 200. For example, the controller 100 may control the memory device 200 in response to a request from the host device. The controller 100 may provide the data read from the memory device 200, to the host device, and store the data provided from the host device into the memory device 200.

The controller 100 may include a storage unit 110, a control unit 120, the error correction code (ECC) unit 130, a host interface 140 and a memory interface 150, which are coupled through a bus 160.

The storage unit 110 may serve as a working memory of the memory system 10 and the controller 100, and store data for driving the memory system 10 and the controller 100. When the controller 100 controls operations of the memory device 200, the storage unit 110 may store data used by the controller 100 and the memory device 200 for such operations as read, write, program and erase operations.

The storage unit 110 may be implemented with a volatile memory. The storage unit 110 may be implemented with a static random access memory (SRAM) or a dynamic random access memory (DRAM). As described above, the storage unit 110 may store data used by the host device in the memory device 200 for the read and write operations. To store the data, the storage unit 110 may include a program memory, a data memory, a write buffer, a read buffer, a map buffer, and so forth.

The control unit 120 may control general operations of the memory system 10, and a write operation or a read operation for the memory device 200, in response to a write request or a read request from the host device. The control unit 120 may drive firmware, which is referred to as a flash translation layer (FTL), to control the general operations of the memory system 10. For example, the FTL may perform operations such as logical to physical (L2P) mapping, wear leveling, garbage collection, and bad block handling. The L2P mapping is known as logical block addressing (LBA).

The ECC unit 130 may detect and correct errors in the data read from the memory device 200 during the read operation. The ECC unit 130 may not correct error bits when the number of the error bits is greater than or equal to a threshold number of correctable error bits, and may output an error correction fail signal indicating failure in correcting the error bits.

In some embodiments, the ECC unit 130 may perform an error correction operation based on a coded modulation such as a low density parity check (LDPC) code, a Bose-Chaudhuri-Hocquenghem (BCH) code, a turbo code, a turbo product code (TPC), a Reed-Solomon (RS) code, a convolution code, a recursive systematic code (RSC), a trellis-coded modulation (TCM), a Block coded modulation (BCM), and so on. The ECC unit 130 may include all circuits, systems or devices for the error correction operation.

The host interface 140 may communicate with the host device through one or more of various interface protocols such as a universal serial bus (USB), a multi-media card (MMC), a peripheral component interconnect express (PCI-E), a small computer system interface (SCSI), a serial-attached SCSI (SAS), a serial advanced technology attachment (SATA), a parallel advanced technology attachment (PATA), an enhanced small disk interface (ESDI), and an integrated drive electronics (IDE).

The memory interface 150 may provide an interface between the controller 100 and the memory device 200 to allow the controller 100 to control the memory device 200 in response to a request from the host device. The memory interface 150 may generate control signals for the memory device 200 and process data under the control of the CPU 120. When the memory device 200 is a flash memory such as a NAND flash memory, the memory interface 150 may generate control signals for the memory and process data under the control of the CPU 120.

The memory device 200 may include a memory cell array 210, a control circuit 220, a voltage generation circuit 230, a row decoder 240, a page buffer 250, a column decoder 260, and an input/output circuit 270. The memory cell array 210 may include a plurality of memory blocks 211 and may store data therein. The voltage generation circuit 230, the row decoder 240, the page buffer 250, the column decoder 260 and the input/output circuit 270 form a peripheral circuit for the memory cell array 210. The peripheral circuit may perform a program, read, or erase operation of the memory cell array 210. The control circuit 220 may control the peripheral circuit.

The voltage generation circuit 230 may generate operation voltages having various levels. For example, in an erase operation, the voltage generation circuit 230 may generate operation voltages having various levels such as an erase voltage and a pass voltage.

The row decoder 240 may be connected to the voltage generation circuit 230, and the plurality of memory blocks 211. The row decoder 240 may select at least one memory block among the plurality of memory blocks 211 in response to a row address RADD generated by the control circuit 220, and transmit operation voltages supplied from the voltage generation circuit 230 to the selected memory blocks among the plurality of memory blocks 211.

The page buffer 250 is connected to the memory cell array 210 through bit lines BL (not shown). The page buffer 250 may precharge the bit lines BL with a positive voltage, transmit/receive data to/from a selected memory block in program and read operations, or temporarily store transmitted data, in response to a page buffer control signal generated by the control circuit 220.

The column decoder 260 may transmit/receive data to/from the page buffer 250 or transmit/receive data to/from the input/output circuit 270.

The input/output circuit 270 may transmit, to the control circuit 220, a command and an address, transmitted from an external device (e.g., the memory controller 100), transmit data from the external device to the column decoder 260, or output data from the column decoder 260 to the external device, through the input/output circuit 270.

The control circuit 220 may control the peripheral circuit in response to the command and the address.

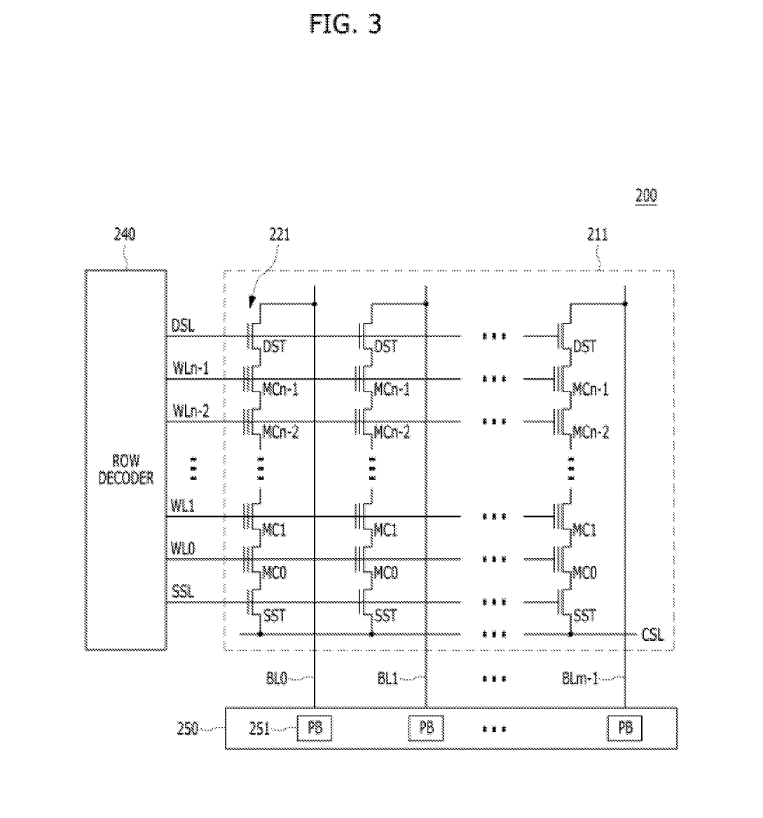

FIG. 3 is a circuit diagram illustrating a memory block of a semiconductor memory device in accordance with an embodiment of the present invention. For example, a memory block of FIG. 3 may be the memory blocks 211 of the memory cell array 200 shown in FIG. 2.

Referring to FIG. 3, the memory blocks 211 may include a plurality of cell strings 221 coupled to bit lines BL0 to BLm−1, respectively. The cell string of each column may include one or more drain selection transistors DST and one or more source selection transistors SST. A plurality of memory cells or memory cell transistors may be serially coupled between the selection transistors DST and SST. Each of the memory cells MC0 to MCn−1 may be formed of a multi-level cell (MLC) storing data information of multiple bits in each cell. The cell strings 221 may be electrically coupled to the corresponding bit lines BL0 to BLm−1, respectively.

In some embodiments, the memory blocks 211 may include a NAND-type flash memory cell. However, the memory blocks 211 are not limited to the NAND flash memory, but may include NOR-type flash memory, hybrid flash memory in which two or more types of memory cells are combined, and one-NAND flash memory in which a controller is embedded inside a memory chip.

DRAM, or fast main memory, is a critical resource in a computing system. The trends for big data and in-memory computing have been pushing for expanded/additional main memory capacity even further. A simple idea is to apply main memory compression to increase the main memory capacity, however, many challenges exist despite many years of research.

The use of compression to increase storage capacity is matured and has been widely deployed for years using techniques such as block-level compression, deduplication, etc., and have achieved good, but variable, compression ratios with only slight increases in latency for data compression/decompression processes and metadata handling etc., without significantly increasing the system cost and power consumption. Since the resulting data blocks are smaller to transfer and to write to storage, some designs can achieve faster performance, using less network, storage bandwidth and less power.

However, the use of compression to increase the capacity of latency-critical main memory (e.g., DRAM) has not been successfully deployed in practice because of many issues and challenges. For example, existing compression algorithms do not translate well when directly applied to the main memory because they require the memory controller to perform non-trivial computations to locate a cache line within a compressed memory page. Also, decompression lies on the critical path of accessing any compressed data. Sophisticated compression algorithms, such as Lempel-Ziv and Huffman encoding, typically achieve high compression ratios at the expense of large decompression latencies that can significantly degrade performance.

Simpler algorithms have been proposed, such as FPC (Frequent pattern compression) or BDI (Base Delta-Immediate) with low decompression latencies and reasonably high compression ratios. However, modern CPU performance is already increasingly bottlenecked by DRAM access latency which has remained mostly the same for many years. Thus, the increases in latency (even 1 or 2 ns) caused by FPC or BDI will have adverse effects to system performance.

For compression algorithms, there are many challenges for its design. For example, main memory compression complicates memory management because the operation system has to map fixed-sized virtual pages to variable-sized physical pages. Also, modern processors employ on-chip caches with tags derived from the physical address to avoid aliasing between different cache lines (as physical addresses are unique, while virtual addresses are not). Thus, the cache tagging logic needs to be modified in light of memory compression to take the main memory address computation off the critical path of latency critical L1 cache accesses. Furthermore, in contrast with normal virtual-to-physical address translation, the physical page offset of a cache line is often different from the corresponding virtual page offset because compressed physical cache lines are smaller than their corresponding virtual cache lines. In fact, the location of a compressed cache line in a physical page in the main memory depends upon the sizes of the compressed cache lines that come before it in that same physical page. As a result, accessing a cache line within a compressed page in the main memory requires an additional layer of address computation to compute the location of the cache line in the main memory, which can be costly.

Thus, compression processes may have the negative effects of, for example, longer and undeterministic latency (and on the critical path of memory accesses), high design complexity that involves CPU, cache logic, memory controllers, addition of hardware compression/decompression engine and other changes such as OS memory management to map fixed virtual page sizes to variable physical page sizes, and high power consumption as a result of the additional operations.

Disclosed herein, systems, methods, devices, and processes that utilize a hybrid memory subsystem (e.g., using slow and fast memory) that stores compressed data in the slow memory (e.g., NAND flash, PCRAM, ReRAM, etc., while data in the fast memory (e.g., DRAM) remains uncompressed. Those of skill in the art will understand from the disclosure herein that the slow memory components may not be exclusively limited to storing only compressed data and the fast memory components may not be exclusively limited to storing only uncompressed data, as both the slow memory and fast memory may be partitioned and/or sections to include various parts dedicated to storing compressed/uncompressed data. Thus, when the OS and/or Applications (e.g., user space processes) access the fast memory (or main memory, system memory, etc.), it will incur little to no decompression latency, little to no complicated cache line offset calculation and metadata handling overhead, and so forth.

The invention disclosed herein enables use of hybrid fast and slow memory to work together. For example, a hybrid memory DIMM with 32 GB DRAM and 512 GB NAND flash storage will have much lower cost than 64 GB DRAM, or 128 GB SCM storage class memory, but the OS will perceive it as greater than or equal to 512 GB byte-addressable fast memory and the systems may run applications effectively with much larger data sets that involves multiple TBs of data in a multiple DIMMs configurations.

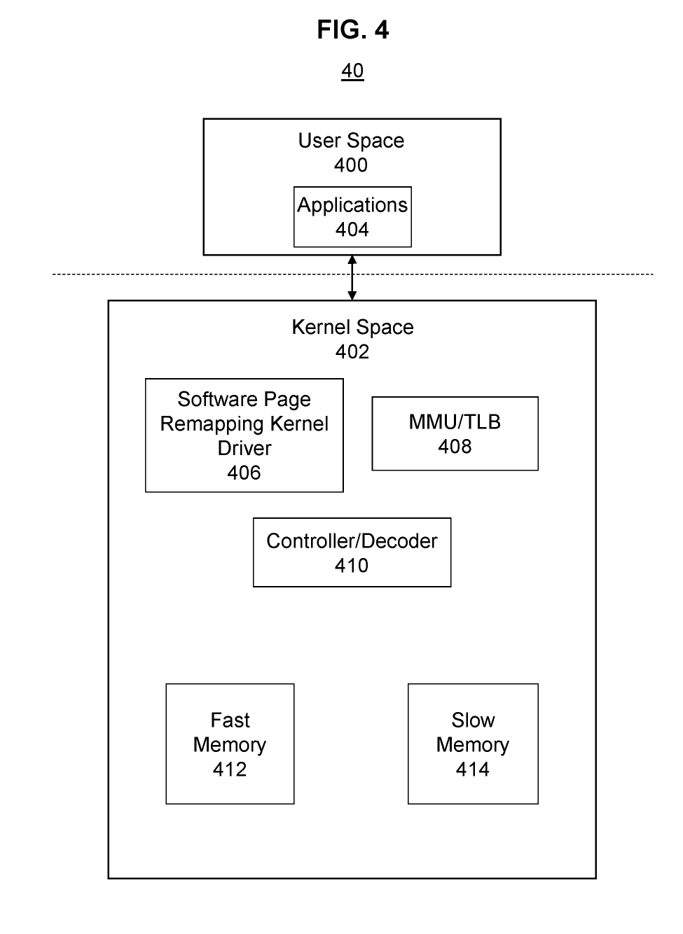

Referring generally to FIG. 4, a system 40 for page remapping is shown. The system 40 includes a user space 400 and a kernel space 402, where the user space 400 and the kernel space 402 are in communication. The user space 400 includes applications 404 which require the components of the kernel space 402 to run. The kernel space 402 includes a software page remapping kernel driver 406, a memory management unit (MMU)/translation lookaside buffer (408), a controller/decoder 410, a fast memory 412 (e.g., DRAM, MRAM, etc.) and a slow memory 414 (e.g., NAND Flash, PCRAM, ReRAM, non-volatile memories (NVM), etc.). The components shown in the system 40 of FIG. 4 and their functionalities are described in detail below.

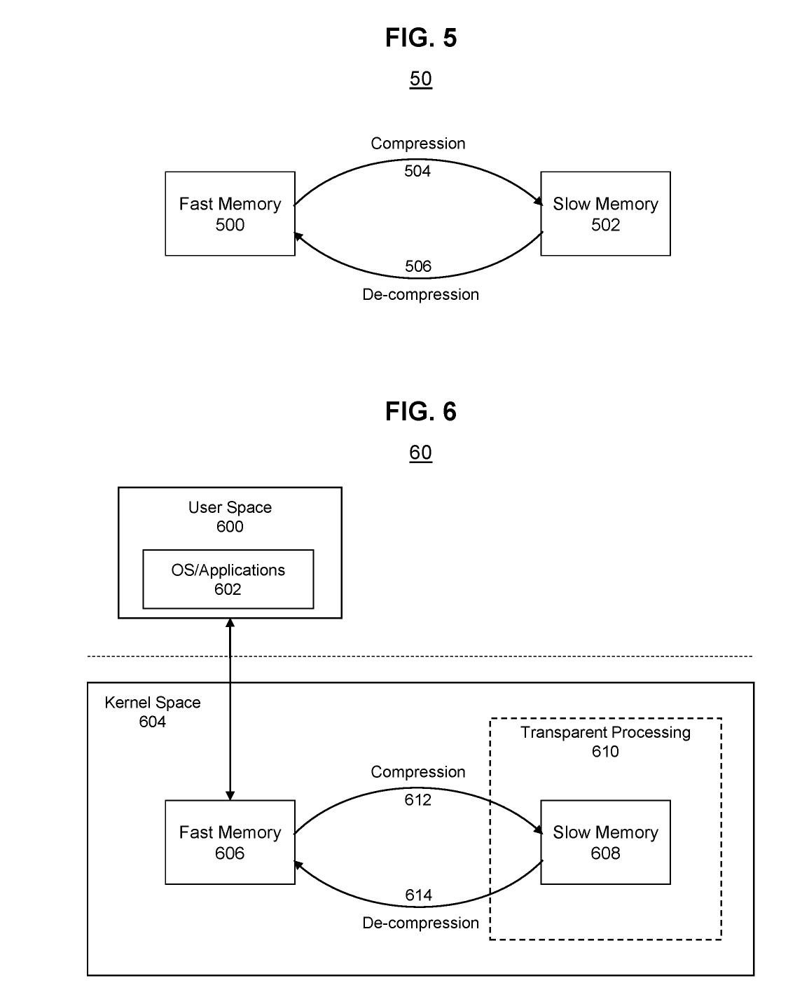

Systems 50 and 60 with hybrid memory subsystems are depicted in FIGS. 5 and 6. The system 50 includes a fast memory 500 and a slow memory 502. System 50 is described for general purposes and may be implemented in a variety of memory systems, devices, processes and methods as will be understood by those of skill in the art from the description herein. In system 50, writing data from the fast memory 500 to the slow memory 502 may involve compression 504 of data. Also in system 50, writing data from the slow memory 502 to the fast memory 500 may involve decompression 506 of data.

System 60 illustrates an example of transparent processing (e.g., transparent meaning not visible or perceived by the OS). The system 60 includes a user space 600 for application execution 602 and a kernel space 604. The user space 600 may be in communication with the kernel space 604 by way or in connection with the fast memory 606. OS and Applications 602 perceive a substantially increased memory capacity (e.g., greater than or equal to 2 time the slow memory 608 capacity plus memory in the fast memory 606 not allocated for a remapping process), but the OS/applications will mostly (and in some embodiments, always) be accessing the fast memory 606.

The system 60 also includes a slow memory 608 that is positioned/configured for transparent processing 610. Put alternatively, when data is being written from the fast memory 606 to the slow memory 608, it may involve compression 612 of the data, and/or when data is being written from the slow memory 608 to the fast memory 606, it may involve decompression 614 of data, and the transparent processing 610 configuration (which is described in more detail below) allows for the compression 612 and the decompression 614 to be performed transparent to (e.g., not visible to, not perceived by) the OS.

In examples of the invention, data in the fast memory 500 and 606 may be uncompressed (and in some embodiments, all the data in the fast memory 500 and 606 may be uncompressed and/or always be uncompressed) so that CPU, OS and applications incur little to no latency by decompression, cache line offset and metadata handling. Data in the slow memory 502 and 608 may be compressed (and in some embodiments, all the data may be compressed and/or always be compressed) to increase effective (perceived) capacity.

Data may be compressed 504/612 when writing a page or performing a “write-back” of a swapped, dirty page back to the slow memory 502 and 608. In the system 60, the compression process 612 and latency is hidden during the process. Data may be decompressed 506/614 when swapping a page from slow memory 502 and 608 to fast memory 500 and 606. In the system 60, the decompression process 614 and latency may be hidden during the process.

As such, system 60 and other examples described herein (including system 50, which may be implemented in a memory system where the compression 504 and decompression 506 processes can be performed transparent to the OS), in decompression and/or compression, cache line offset calculation and metadata handling overheads are “hidden” and may be handled during a page remapping process prior to the OS/applications 602 accessing the target memory locations.

In some embodiments, the hybrid memory inventions disclosed herein utilize a software page remapping process, and by hiding the compression/decompression processes during the page swapping process of the page remapping, the systems enable OS/application 602 transparent memory compression while substantially increasing the perceived main memory capacity by the OS and applications.

In some embodiments disclosed below, a software page remapping scheme is utilized, where the page remapping scheme is also transparent to the OS/applications. By virtue that the software page remapping scheme is OS- and Application transparent, and it guarantees that all (or substantially all) accesses targeted to the slow memory will be remapped (or replicated or swapped) to fast memory first before the accesses happen, by hiding the compression/decompression process during this page remapping process, the invention enables completely OS- and Application-transparent memory compression that can substantially increase effective memory capacity perceived by the OS- and Applications but incurs zero decompression latency, cache line offset calculation and metadata handling overhead as typically associated with main memory compression systems.

The invention disclosed herein may be implemented in a system configured for software page remapping, such as the remapping systems described in U.S. Provisional Application No. 62/280,430 titled “MECHANISM ENABLING THE USE OF SLOW MEMORY TO ACHIEVE BYTE ADDRESSABILITY AND NEAR-DRAM PERFORMANCE WITH PAGE REMAPPING SCHEME,” the contents of which are incorporated herein by reference.

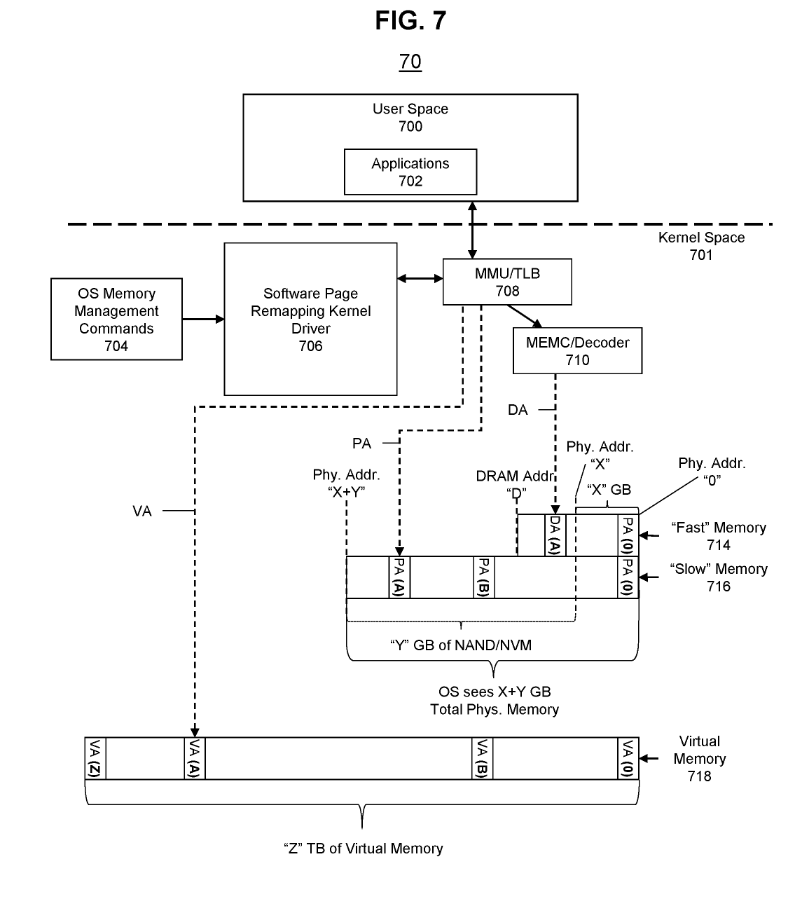

An example system 70 for page remapping that may be utilized with the compression systems, methods, processes and devices disclosed herein is shown in FIG. 7 according to aspects of the invention. Those of skill in the art will understand that the invention is not limited to implementation within systems for page remapping as is further described below. The system 70 includes a fast memory portion (e.g., DRAM, etc.) 714, a slow memory portion (e.g., NVM, NAND, etc.) 716, and a virtual memory VM 718.

The total physical fast memory space 714 (referred to herein as DRAM, although other suitable fast memories may be utilized to effectuate the invention as will be understood by those of skill in the art and as described above) is shown as “D”. Out of “D” GB, “X” GB of DRAM are mapped and visible to the OS. In other words, “D-X” GB of DRAM may be used as a remap buffer. The total physical slow memory space 516 (referred to herein as NAND and/or NVM, although other suitable slow memories may be utilized to effectuate the invention as will be understood by those of skill in the art and as described above) is “Y” GB, and thus, the total system memory/total physical memory as perceived by the OS is “X+Y” GB. The amount of virtual memory/virtual address 718 space is Z TB.

The system 70 may include a user space 700 and a kernel space 701 (e.g., the components/operations below the dashed line of kernel space 701). From the user space 700, OS/applications 702 may be executed. The kernel space 701 includes a module for transmitting OS memory management commands 704, a software page remapping kernel driver (SPRKD) 506, an MMU/TLB (memory management unit (e.g., controller)/translation lookaside buffer) 708, and/or an MEMC/decoder (memory controller decoder) 710.

In typical OS environment, when OS accesses (or allocates) VA location “A”, if the page containing “A” is not already mapped to the system memory, it will generate a page fault, the OS will retrieve that page from storage (e.g., hard disk drive or SSD) and copy to the system memory. However, as seen in FIG. 7, since the OS perceives the total system memory as “X+Y” GB, if the memory page allocated falls into the NVM 716 address range (e.g., between “X to X+Y” GB), the subsequent read/write access to that page may be slow due to, for example, the NAND 716 being substantially slower than DRAM 714, the read/write accesses involving a page (block mode) access and is not byte addressable, and/or it needs to call a block mode driver to perform block mode accesses.

The system 70 may be configured to redirect subsequent accesses to the slow memory 716 to the DRAM 714 (at least transparently, or in a way that is not visible to or perceived by the OS), therefore emulating the entire NAND 716 space from “X to X+Y” GB to be operable as a fast memory (e.g., such as fast memory 714), thus supporting random, byte addressable read/write accesses. The SPRKD 706 may be configured to initiate the page remapping by intercepting OS memory management commands 704 and performing a secondary translation, or page remapping.

As an example, the SPRKD 706 is configured to intercept the MM commands 704 that maps the virtual address VA=“0 to Z” TB to physical address PA=“X to X+Y” GB (e.g., in the slow memory space 716) and to convert the maps for VA=“0 to Z” TB to PA=“X to D” GB range so all accesses to VA=“0 to Z” TB will be redirected to the DRAM 714 remap buffer space between “X to D”.

After intercepting the MM commands 704, the SPRKD 706 may be configured to check if a remapping needs to be performed by looking for an empty page in the DRAM 714 remap buffer space (e.g., between “X to D”) and perform the following example steps. If an empty page is available, the SPRKD 706 may perform the remapping, which may simply be page replication to copy the NVM 716 page to the empty DRAM 714 remap buffer page. If an empty page is not available, an eviction algorithm may be utilized to choose a page to evict. For example, is a page chosen to evict is clean, it can simply be discarded and the page replication can be performed. If the page chosen is dirty, the SPRKD 706 may be configured to write-back that page to the corresponding NVM 716 page before performing the remapping.

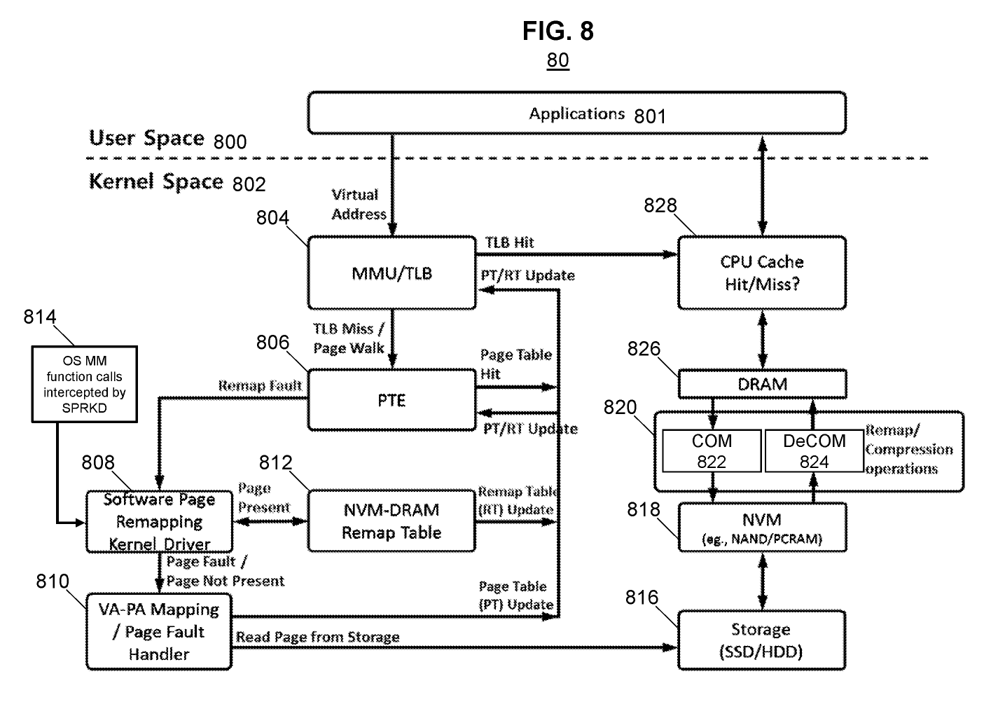

Referring next to FIG. 8, a diagram 80 of example CPU and OS operations is shown. As seen in FIG. 8, there is a user space 800 in which the applications 801 execute, and a kernel space 802. In the operation, the utilized components may include an MMU/TLB 804, a page table (PT) including page table entries (PTE) 806, a software page remapping kernel driver (SPRKD) 808, a virtual address (VA) to physical address (PA) mapping/page fault handler 810, an NVM-DRAM remap table 812, a storage 816 (which may include the total storage of the slow and fast memory, although these components are depicted separately in FIG. 8 for ease of explanation), a slow memory/NVM 818, and a DRAM/fast memory 826. The system/process 80 may also include a CPU cache hit/miss check 828.

Since the SPRKD 808 will convert all accesses to NAND/NVM 818 address space and remap them to the DRAM 826 remap buffer space at “X to D” GB by intercepting the OS MM function calls/commands at 814, OS accesses to the slow memory space 818 are always remapped (redirected) to DRAM such that the OS thinks it is accessing fast, byte-addressable DRAM memory.

In general, the SPRKD 808 may be configured to perform two functions. First, the SPRKD 808 intercepts the OS MM function calls 814. When OS needs to change the VA (virtual address) to PA (physical address) mapping, the SPRKD 808 will check if the page is present in the NVM-DRAM Remap Table 812 first. If hit, it will perform “RT Update” (Remap Table Update) to the PTE 806 and TLB 804 using the RT (Remap Table) info. If miss, it will treat it as Page Fault and pass it to the OS Page Fault handler 810.

Second, in a normal TLB miss, the TLB miss handler will perform a “page walk” to determine if a page is mapped in PT (hit) or not in the PT (miss, which will be treated as “remap fault”) and then passed to the SPRKD 808. At the SPRKD 808, for a PT hit, it may be configured to perform a remap, update the remap table 812 and perform a TLB update. At the SPRKD 808, for a PT miss, it may be configured to perform a similar action as the page fault to load the page from storage, perform VA-PA mapping, PT update, TLB shootdown to other processors, TLB update to the target processor, and then retry the memory access that triggers the TLB miss.

Although the system 80 shows an example of a CPU process for page remapping with an SPRKD 808, those of skill in the art will recognize other suitable processes and configurations for effectuating the invention without departing from the invention from the disclosure herein.

As shown in the system/process 80, the page remapping process that is performed transparent to the OS also incorporates compression operations 820 into its remapping operations. Operations and transfers between the fast memory 826 and the slow memory 818 required to conduct the page remapping steps may involve compression operations 822 from the fast memory 826 to the slow memory 818 and decompression operations 824 from the slow memory 818 to the fast memory 826. These operations are described in detail below.

In some embodiments of the invention, the SPRKD may compress the page chosen to be evicted first before performing the write-back to the compressed page to the slow memory, and the the SPRKD may decompress the target page chosen to be replicated, followed by replicating from slow memory to fast memory.

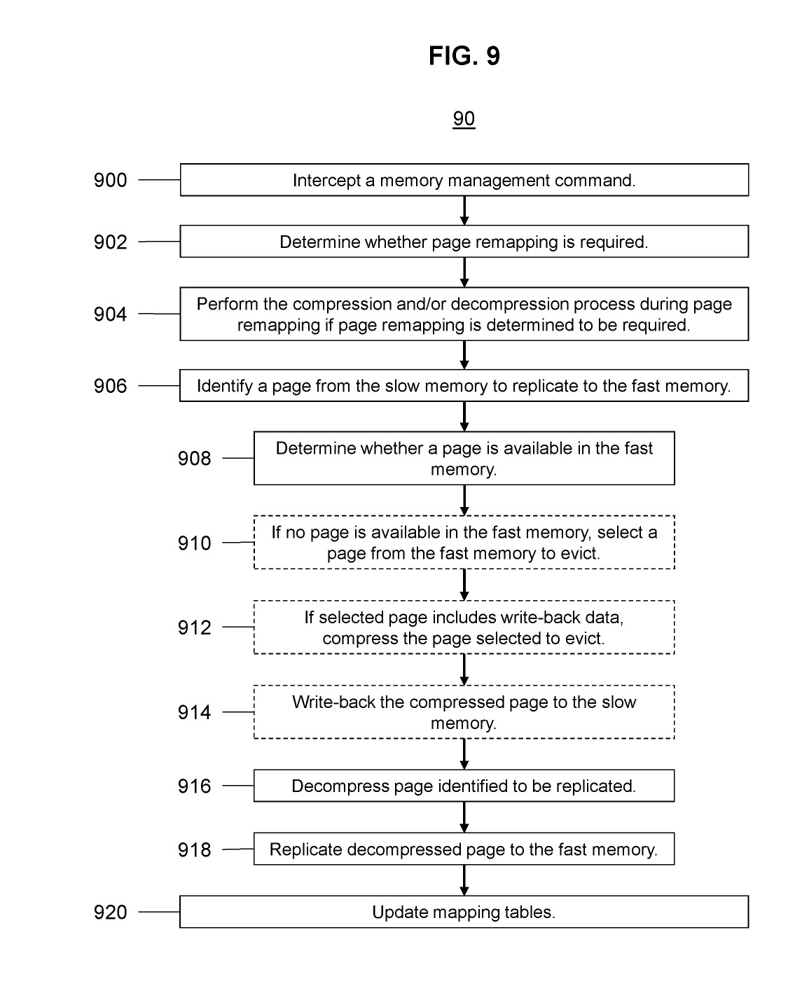

FIG. 9 is a flowchart 90 of steps in a method/process for performing page remapping and compression operations transparent to the operating system, and will be described with respect to the components in FIG. 8 specifically for ease of description, although the components described in previous figures may be also configured to perform the steps in flowchart 90.

At step 900, a memory management command 814 is intercepted. For example, the SPRKD 808 may be configured to intercept the memory management command 814. The memory management command 814 may include a command or access to memory that maps the VA=“0 to Z” to physical addresses (PA)=“X to Y” of the NAND portion 716.

At step 902, it is determined whether page remapping is required. For example, the SPRKD 808 may be configured to determine whether page remapping is required. If page remapping is not required (e.g., the access is for an address that is already in the DRAM buffer space and/or no compression or decompression is required for the memory management command 814), the SPRKD 808 may default so the OS page fault handler 810 may read the page from storage 816 and perform the VA-PA mapping.

At step 904, if it is determined that page remapping is required, the compression and/or decompression operations 820 are configured to be performed during the page remapping process. For example, the SPRKD 808 may be configured to initialize/perform the compression and/or decompression operations 820 during the remapping operation.

At step 906, a page from the slow memory 818 is identified to be replicated to the fast memory 826. The SPRKD 808 may be configured to identify the page from the slow memory 818 to be replicated to the fast memory 826.

At step 908, it is determined whether a page is available in the fast memory 826 such that the page identified at step 906 can be replicated (e.g., written) to the fast memory 826 at the empty page. As an example, the SPRKD 808 may be configured to determine whether a page is available in the fast memory 826.

Steps 910-914 describe an example set of steps taken when it is determined at step 908 (e.g., the SPRKD 808 determines) that there is not a page available in the fast memory 826.

At step 910, if no page is available in the fast memory 826, a page from the fast memory is selected to evict. As used herein, eviction may refer to algorithms (such as those described in U.S. Provisional Application No. 62/280,430 that was previously incorporated by reference herein) which free up a page or pages or, otherwise, space in the fast memory 826 such that remapping/replication/compression/decompression/etc. may be performed. If the selected page does not include data that needs to be written back to the slow memory 818, then the process may proceed to step 916. Otherwise, the process continues at steps 912-914.

Once the page is selected, at step 912, if the selected page includes write-back data (e.g., data to be written back to the slow memory 818), the page selected to evict (e.g., the data in the page) is compressed. For example, the SPRKD 808 may be configured to compress the selected page. Since the page is previously in the fast memory 826, it is (likely) stored in an uncompressed state, since the OS accesses the fast memory 826 and these accesses are designed to have little to no latency. Therefore, to improve the perceived space of the slow memory 818, and because the data in the page needs to be written-back, the compression operation 822 may occur at step 912. Since the remapping operation is performed transparent to the OS, and since the compression operation 822 is also being performed during the remapping operation, the compression operation 822 is also performed transparent to the OS, thus reducing latency and including other benefits as is described herein.

At step 914, once the page/data selected to evict is compressed (e.g., the compression operation 822 finished), the compressed page/data is written-back to the slow memory 818. In some embodiments, the SPRKD 808 (e.g., by way of the page fault handler 810) is configured to write-back the compressed selected page to the slow memory 818. Once the data is written back to the slow memory 818, the selected page may be evicted (e.g., the data in the page may be removed, thus freeing up the space in the fast memory 826 for the remapping operation).

At step 916, the page identified to be replicated is decompressed. The page that is identified to be replicated may be stored on the slow memory 818, and thus, may be stored in a compressed state. Since it is preferred that the data to be stored in the fast memory 826 be done so in an uncompressed state, the decompression operation 824 may be conducted at this step in the remapping process. In one example, the SPRKD 808 is configured to conduct/initiate the decompression process 824. Since the decompression operation 824 is performed during the remapping process (which, as detailed above, is performed transparent to the OS), the decompression operation 824 may also be performed transparent to the OS.

At step 918, the decompressed page is replicated to the fast memory 826. For example, the SPRKD 808 may be configured to initiate the replication process/replicate the decompressed page to the fast memory 826. This replication, which is a usual step in page remapping schemes such as those described herein, improves the operation of the memory device, since the decompression has occurred prior to the completion of the remapping. Thus, the replicated (remapped) page is decompressed at the time it is written to the fast memory 826. This is advantageous because, not only is it transparent to the operation system, but an additional step following the remapping is removed. Traditionally, after the remapping is done, no decompression is performed, and thus, after the replication of the page, the system has to conduct the decompression of the page as it is stored in the fast memory 826. This would not be transparent to the OS and would decrease the speed of the operation. Having the page remapping and the compression/decompression operations performed in this way permits transparent remapping and compression/decompression operations, removing non-transparent steps and increasing performance.

The systems, methods, processes and devices disclosed herein may be applied to other hybrid or heterogeneous memory subsystem that does not utilize the remapping page schemes described above, and these are referenced as examples to illustrate how the compression/decompression process can be done in an OS- and Application-Transparent manner, and how part or all of the latency can be offset or “hidden” to achieve no or little performance impact.

With compressed data blocks that are smaller in size, the systems, methods, processes and devices disclosed herein may reduce the wear and improve the endurance and life of the slow memory media.

With compressed data blocks that are smaller in size, the read/write time and memory bandwidth may be reduced, and this can either partially offset, fully offset or even more than compensate the latencies incurred by the (hidden) compression/decompression process during the page remapping/swapping/replication process. Memory compression using the invention described herein may enable little to no performance impact while enjoying all other benefits associated with memory compression.

If the “slow memory” is “remote memory”, whether it is located in another server, another datacenter or a “Memory Pool” server etc., and whether it is NAND, SCM/NVM or even DRAM over some form of network or fabrics, this invention disclosed herein may support it and can substantially reduce the network bandwidth, fabric bandwidth and memory bandwidth because network/fabric traffic to access remote memory only occurs when performing page remapping between local fast and slow remote memory, thus normal OS and application accesses to the remote memory are directed to remapped pages in the fast local memory, and smaller, compressed pages will traverse the network, fabric, and memory bus interfaces, hence reducing bandwidth, latency, and power accordingly.

In one embodiment, when implemented with a software page remapping process, there is no hardware changes to host CPU, host memory controller or memory channel interfaces. Thus, the invention disclosed herein can work in existing and future JEDEC memory socket (eg., JEDEC DDR3, DDR4), is compatible with other existing JEDEC (or non-JEDEC) memory on the same channel, can also work on all non-JEDEC memory interfaces (e.g., IBM/OpenPOWER DMI interface, etc.), and is compatible with OS-level NUMA mechanism since this invention is done in a way “transparent” to OS.

The present invention further enhances software page remapping schemes by increasing the effective, perceived memory by a typical 2:1 or higher target compression ratio. Using the same example above, a hybrid memory DIMM with physical 32 GB DRAM+256 GB NAND flash can now be perceived by the OS and Applications as greater than or equal to 512 GB random-access, byte-addressable fast memory, while still having much lower cost than 64 GB DRAM, or 128 GB SCM storage class memory. Hence, the present invention enables very cost-effective deployment of big data applications and in-memory computing environments.

The invention disclosed herein may be utilized with other hardware or software page swapping/remapping schemes, and it may be utilized whether the page remapping scheme is completely OS/application transparent or not. The invention will still provide substantial benefits by hiding all or part of the compression/decompression overhead and associated latencies as opposed to the processes where the decompression latency overhead is in the critical path of the main memory accesses and negatively impact system performance.

Examples of the invention can adopt all lossless compression algorithms without restrictions, though low latency algorithms with good average compression ratio of 2:1 or higher are preferred for practical implementations. Algorithms such as Lempel-Ziv-based (LZO, LZ4, LZ77, LZ78), Huffman encoding, FPC (Frequent Pattern Compression) or BDI (Base-Delta-Immediate compression) are all possible options for this invention.

Embodiments may support lossy compression algorithms if the OS and SPRKD are application-aware. For example, the SPRKD can apply lossless compression to the pages used for code or normal application data, and can apply lossy compression to pages allocated as display frame buffer which support psychovisually lossless, but actually uses lossy compression (e.g., VESA Display Stream Compression (DSC) v1.1, etc.).

The invention disclosed herein supports either hardware or software compression/decompression methods, and hardware accelerators may have lower latency and higher performance. No changes are required to the CPU, cache tagging logic or the host memory controller to add the metadata caches, etc.

The invention disclosed herein allows highly flexible implementation to couple either software or hardware page remapping/swapping/replication mechanisms with either software or hardware compression methods. Thus, it ranges from zero hardware cost to a modest cost to add compression hardware and related DMA logic for high performance implementation.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A memory system, comprising:
a memory storage including a fast memory portion and a slow memory portion;
a software page remapping kernel driver (SPRKD) suitable for:
intercepting a memory management command generated by an operating system;
at least one of:
compressing data to be written from the fast memory portion to the slow memory portion prior to execution of the operating system memory management command; and
decompressing data to be written from the slow memory portion to the fast memory portion prior to execution of the operating system memory management command; and
transferring either the compressed data to be written to the slow memory portion or the decompressed data to be written to the fast memory portion; and
a controller suitable for executing the memory management command after the transferring by the SPRKD such that the compressing or decompressing of data is performed transparent to the operating system.

2. The memory system of claim 1, wherein the SPRKD is further suitable to perform the compressing or decompressing during a page remapping process.

3. The memory system of claim 1, wherein the SPRKD is further suitable for decompressing by:
identifying a page from the slow memory to replicate to the fast memory;
determining whether a page is available in the fast memory; and
decompressing the page identified to be replicated.

4. The memory system of claim 3, wherein, when the SPRKD determines no page is available in the fast memory, the SPRKD is suitable for selecting a page from the fast memory to evict.

5. The memory system of claim 1, wherein the SPRKD is further suitable for compressing by:
selecting a page to evict from the fast memory that includes write-back data; and
compressing the write-back data of the selected page.

6. The memory system of claim 5, wherein the SPRKD is further suitable for writing-back the compressed page to the slow memory.

7. A method, comprising:
intercepting, with a software page remapping kernel driver (SPRKD), a memory management command generated by an operating system;
at least one of:
compressing, with the SPRKD, data to be written from a fast memory portion of a memory storage to a slow memory portion of the memory storage prior to execution of the operating system memory management command; and
decompressing, with the SPRKD, data to be written from the slow memory portion to the fast memory portion prior to execution of the operating system memory management command; and
transferring, with the SPRKD, either the compressed data to be written to the slow memory portion or the decompressed data to be written to the fast memory portion; and
executing, with a controller, the memory management command after the transferring by the SPRKD such that the compressing or decompressing of data is performed transparent to the operating system.

8. The method of claim 7, further comprising performing the compressing or decompressing steps during a page remapping process.

9. The method of claim 7, wherein the decompressing step further comprises:
identifying, with the SPRKD, a page from the slow memory to replicate to the fast memory;
determining, with the SPRKD, whether a page is available in the fast memory; and
decompressing, with the SPRKD, the page identified to be replicated.

10. The method of claim 10, wherein when it is determined no page is available in the fast memory, further comprising selecting, with the SPRKD, a page from the fast memory to evict.

11. The method of claim 7, wherein the compressing step further comprises:
selecting, with the SPRKD, a page to evict from the fast memory that includes write-back data; and
compressing, with the SPRKD, the write-back data of the selected page.

12. The method of claim 11, further comprising writing-back the compressed page to the slow memory.

13. A memory device, comprising:
a memory storage including a fast memory portion and a slow memory portion;
a software page remapping kernel driver (SPRKD) configured to:
intercept a memory management command generated by an operating system;
at least one of:
compress data to be written from the fast memory portion to the slow memory portion prior to execution of the operating system memory management command; and
decompress data to be written from the slow memory portion to the fast memory portion prior to execution of the operating system memory management command; and
transfer either the compressed data to be written to the slow memory portion or the decompressed data to be written to the fast memory portion; and
a controller configured to execute the memory management command after the transferring by the SPRKD such that the compressing or decompressing of data is performed transparent to the operating system.

14. The memory device of claim 13, wherein the SPRKD is further configured to perform the compressing or decompressing during a page remapping process.

15. The memory device of claim 13, wherein the SPRKD is further configured to decompress by:
identifying a page from the slow memory to replicate to the fast memory;
determining whether a page is available in the fast memory; and
decompressing the page identified to be replicated.

16. The memory device of claim 15, wherein, when the SPRKD determines no page is available in the fast memory, the SPRKD is configured to select a page from the fast memory to evict.

17. The memory device of claim 13, wherein the SPRKD is further configured to compress by:
selecting a page to evict from the fast memory that includes write-back data; and
compressing the write-back data of the selected page.

18. The memory system of claim 17, wherein the SPRKD is further configured to write-back the compressed page to the slow memory
